(19) United States
(12) Patent Application Publication
(10) Pub. No.: US 2014/0167786 A1
(43) Pub. Date: Jun. 19, 2014

(54) Current Sensor For Power Measurement Applications

(71) Applicant: SCHNEIDER ELECTRIC USA, INC., Palatine, IL (US)

(72) Inventors: Efrain Gutierrez, Nuevo Leon (MX); Mauricio Diaz, Nuevo Leon (MX); Gustavo Garza Sanchez, Nuevo Leon (MX)

(73) Assignee: SCHNEIDER ELECTRIC USA, INC., Palatine, IL (US)

(21) Appl. No.: 13/715,492

(22) Filed: Dec. 14, 2012

(51) Int. Cl. G01R 21/00; G01R 21/06

(52) U.S. Cl. CPC G01R 21/00; G01R 21/06
USPC 324/654

(57) ABSTRACT

An electrical system with a power distribution system has a current sensor for directly monitoring electrical power in a current conductor, the current sensor including a printed circuit board (PCB), a current transducer, and integrated conditioning electronics. The PCB has a non-ferromagnetic core through which the current conductor is inserted. The current transducer is for sensing the electrical power in the current conductor and is in the form of a sensing coil printed around the non-ferromagnetic core. The conditioning electronics are embedded into the PCB for processing a data signal based on the monitored electrical power of the current conductor.

### FIELD OF THE INVENTION

This invention is directed generally to electrical systems, and, more particularly, to a current sensor with a current transducer printed on a circuit board.

### BACKGROUND OF THE INVENTION

Electrical power in electrical systems is generally supplied from a power source to a power distribution unit and, then, diverted to one or more individual branch circuits. The individual branch circuits provide electrical power to various power loads, such computers, printers, heating devices, lighting devices, etc.

One problem with some present electrical systems is that sensors are not individually installed for each branch circuit connected to the power distribution unit. As such, monitored current levels fail to adequately inform exactly which power loads are causing problems, which branch circuits can handle additional loads, and or which branch circuits are near capacity. Being unable to timely determine, for example, which power load may cause overloading of a conductor cable beyond its nominal current range, can be catastrophic for hospitals, airports, banks, and other industrial facilities that depend heavily on their electric systems to operate smoothly. Heavy human and/or financial losses can result from an electrical failure in these types of environments.

Another problem with some present electrical systems is that they use conventional sensors that are bulky and expensive. For example, such sensors include conventional current transformers and hall effect transducers. The large size of these types of sensors greatly increases costs and/or labor associated with manufacturing and installation. For example, conventional current sensors are difficult, or even impossible, to mount in tight and/or crowded spaces.

### SUMMARY OF THE INVENTION

In an implementation of the present invention, a current sensor is enclosed within a distribution enclosure and has a printed circuit board (“PCB”) with embedded electronics. The embedded electronics directly meter electrical power in a current conductor that is inserted through an aperture of the PCB. The current conductor carries electrical current for high-power electrical equipment, e.g., switchgear or switchboard equipment. A sensing coil is printed around the aperture and provides an input power signal to the embedded electronics. In turn, the embedded electronics process the input power signal and determine measured power values that are displayed, for example, on an exterior value display.

In another implementation of the present invention, an electrical system with a power distribution system has a current sensor for directly monitoring electrical power in a current conductor, the current sensor including a printed circuit board (PCB), a current transducer, and integrated conditioning electronics. The PCB has a non-ferromagnetic core through which the current conductor is inserted. The current transducer is for sensing the electrical power in the current conductor and is in the form of a sensing coil printed around the non-ferromagnetic core. The conditioning electronics are embedded into the PCB for processing a data signal based on the monitored electrical power of the current conductor.

In another alternative implementation of the present invention, an electrical power distribution system includes an enclosure having an exterior value display, the value display displaying measured electrical values. The system further includes a current conductor enclosed within the enclosure and a current sensor for directly monitoring electrical power in the current conductor. The current sensor is enclosed within the enclosure and includes a coreless printed circuit board (PCB), through which the current conductor is inserted, and a current transducer for sensing the electrical power in the current conductor. The current transducer is a sensing coil printed around an internal aperture of the PCB. The current sensor further includes electronics embedded in the PCB for receiving an input power signal from the current transducer and for outputting, in real time, the measured electrical values to the value display.

Additional aspects of the invention will be apparent to those of ordinary skill in the art in view of the detailed description of various embodiments, which is made with reference to the drawings, a brief description of which is provided below.

### BRIEF DESCRIPTION OF THE DRAWINGS

The invention may best be understood by reference to the following description taken in conjunction with the accompanying drawings.

FIG. 1 is an illustration of an electrical system with a power distribution system.

FIG. 2A is a perspective view of a front panel of the distribution system of FIG. 1.

FIG. 2B is a perspective view of the distribution system covered by the front panel of FIG. 2A.

FIG. 2C is front enlarged view of the front panel of FIG. 2A illustrating current measurements.

FIG. 3 is a front perspective view of a current sensor and a current conductor.

FIG. 4 is a diagrammatic illustration of a current sensor metering electrical power in a conductor.

FIG. 5 is a front view of a current sensor with a three-phase arrangement.

FIG. 6A is a front perspective view of an oval current sensor for sensing current in a current conductor having a stacked configuration.

FIG. 6B is a front view illustration of the oval current sensor of FIG. 6A being split into two board sections.

### DETAILED DESCRIPTION OF THE ILLUSTRATED EMBODIMENTS

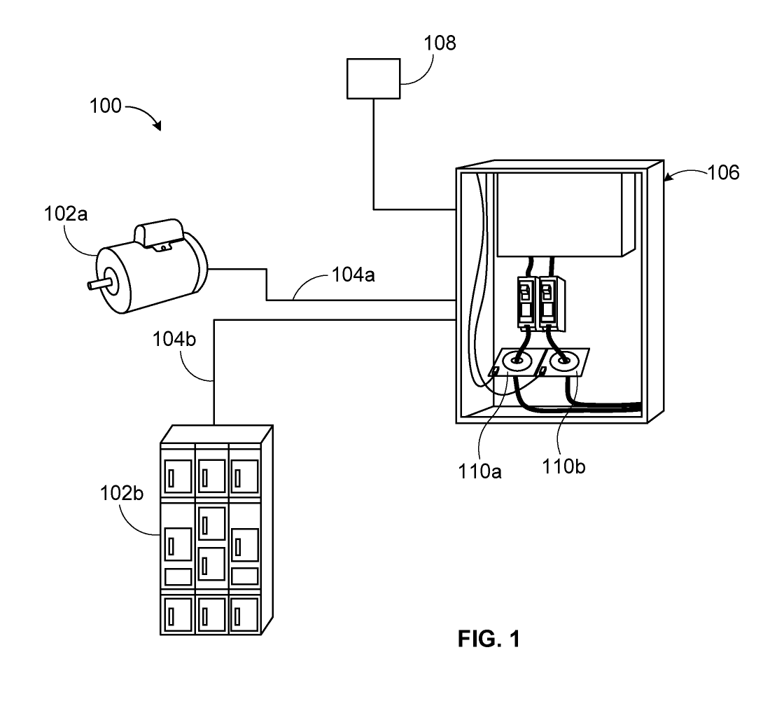

Referring to FIG. 1, an electrical system 100 represents an energy management system or a smart grid electrically coupled to a plurality of electrical loads 102a, 102b via respective current conductors 104a, 104b. Generally, the electrical system 100 provides current metering devices for measuring electrical power in one or more of the current conductors 104a, 104b. Specifically, the electrical system 100 includes a power distribution system 106 that receives electrical power from a power source 108 and is communicatively coupled to the electrical loads 102a, 102b for transmitting electrical power via the current conductors 104a, 104b. The power distribution system 106 can include, for example, a panelboard, a switchboard, a switchgear, etc. The electrical loads 102a, 102b include, for example, a motor 102a and switchgear equipment 102b.

In other examples, more or less loads can be coupled to the power distribution system 102, including, for example, a server, a lighting system, a non-ferromagnetic-conditioning system, a power sub-distribution system, another meter device, etc. The current conductors 104a, 104b can be in the form of wires made of conductive materials for allowing electrical current to flow through respective circuits. Alternatively, the current conductors 104a, 104b can be in the form of cables, flat laminations, or extrusions, including stacked-configurations of conductors.

To monitor power consumption in the electrical system 100, the power distribution system 106 includes current sensors 110a, 110b that measure electrical power transmitted through the current conductors 104a, 104b. As described in more detail below, the current sensors 110a, 110b provide, respectively, independent power metering for the current conductors 104a, 104b. Also, according to one example, the current sensors 110a, 110b have an electrical output range of about one ampere to about five amperes.

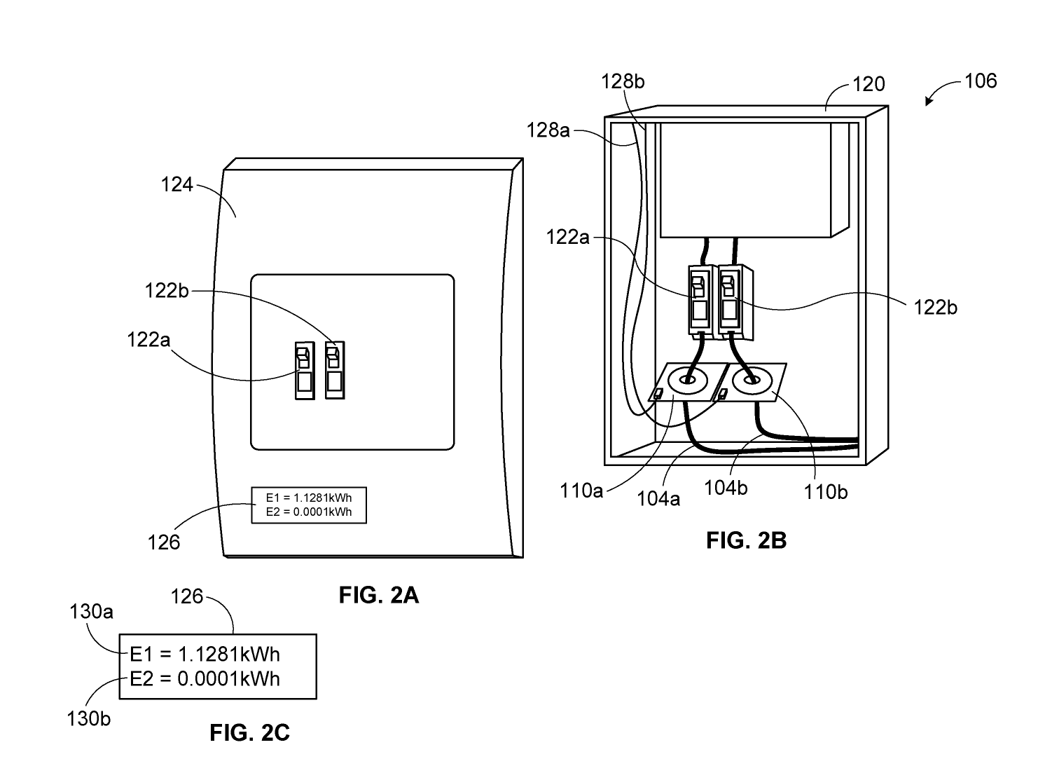

Referring to FIGS. 2A-2C, the power distribution system 106 includes a distribution enclosure 120 in which a pair of single circuit breakers 122a, 122b are installed for protecting respective branched circuits. The branched circuits receive electrical current via respective current conductors 104a, 104b. The enclosure 120 houses the current conductors 104a, 104 and the current sensors 104a, 104b.

The enclosure 120 includes a cover 124 having a value display 126 on a front exterior surface. The value display 126 is viewable without requiring internal access to the enclosure 120. Furthermore, the value display 126 includes a two-line screen that displays current values in real time.

The enclosure 120 further includes the current sensors 110a, 110b for sensing electrical current in the current conductors 104a, 104b. The current sensors 110a, 110b output signals indicative of the sensed current via signal lines 128a, 128b. Current values 130a, 130b of the sensed electrical current are displayed on the value display 126. For example, the current values 130a, 130b are “1.1281kWh” for the first current conductor 104a and “0.0001kWh” for the second current conductor 104b. Alternatively, the displayed values can be any electrical value, e.g., a power value, a voltage value, etc.

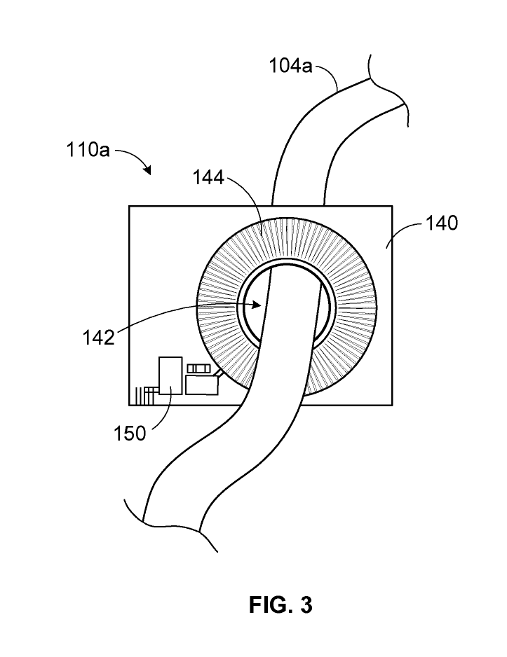

Referring to FIG. 3, reference will be made solely to a first current sensor 110a of the current sensors 110a, 110b. However, it is understood that the description of the current sensor 110a also refers, as applicable, to a second current sensor 110ab. The current sensor 110a includes a printed circuit board (PCB) 140 with a non-ferromagnetic core 142 through which the current conductor 104a is inserted. According to the illustrated example, the non-ferromagnetic core 142 is an air core.

The PCB 140 has printed layers uniformly accommodated in different patterns and closed forms, including circular, elliptical, or rectangular. Optionally, the PCB 140 can include embedded steel sheet layers in-between the printed layers. An exemplary thickness for the PCB 140 can range from approximately 1.6 millimeters to approximately 5 millimeters. One benefit of using the PCB 140 for the current sensor 110a is that the current sensor design can be laid out on a two dimensional board, which is easy to design.

The current sensor 110a further includes a current transducer 144 for sensing the electrical power in the current conductor 104a. The current transducer 144, according to one example, is in the form of a sensing coil that is printed around the non-ferromagnetic core 142. The sensing coil 144 can sense current in any amperage range, e.g., from a few Amperes in loadcenters to thousands of Amperes in panelboards. According to one example, the sensing coil 144 is adapted to sense current in a high-amperage system, such as in switchgear or switchboard electrical equipment. The sensing coil 144 can be a Rogowski coil, which consists of a helical coil of wire with a lead from one end returning through the center of the coil to the other end so that both terminals are at the same end of the coil. The sensing coil, for example, is wrapped on the PCB 140 around the non-ferromagnetic core 142 through which the current conductor 104a is inserted.

The current sensor 110a provides sensing technology that is capable of being miniaturized and easily industrialized. Accordingly, some advantages of the current sensor 110a include isolated measurement of electrical current, high manufacturing reproducibility, and low manufacturing cost. For example, printed coil can provide manufacturing savings by a factor of ten in contrast to iron core sensors (e.g., approximately $50 for 40 coil sensors vs. approximately $500 for 40 iron core sensors). In another example, the small size of the current sensor 110a allows compact metering of branched circuits and, therefore, enables smart metering (e.g., where apartments are on branch circuits). As such, lower bulk of the metering system results in a lower metering expense.

Another advantage of current sensor 110a stems from the lack of ferromagnetic material. Because the sensing coil 144 does not contain iron, higher currents can be measured using the same sensor and the sensor bandwidth is much higher than in conventional sensors. Conventional Rogowski coil sensors require electronics for conditioning their signal. Having the current transducer printed on a PCB allows required electronics to be mounted on the same PCB used for sensing the current. In contrast to conventional Rogowski sensors, the current sensor 110a includes small sensing electronics right next to the sensing coil 144 for measuring small current signals. Furthermore, the current sensor 110a has low power loss, which, in turn, means that low heat is generated. As such, low heat further helps in having small sensing electronics closer to the current sensor 110a because cooling the electronics does not cause a problem.

Based on the inherent electronic nature of the current sensor 110a, yet another advantage of the current sensor 110a is that it can be easily calibrated. For example, an electronics device adjustment, such as a potentiometer, can be used to calibrate the current sensor 110a.

The current sensor 110a further includes its own conditioning electronics 150, which are embedded into the PCB 140. The conditioning electronics 150 provide individual and dedicated on-board processing circuitry for monitoring the electrical power of the current conductor 104a. The conditioning electronics 150 include, for example, all data processing for accomplishing the monitoring of the electrical power. Accordingly, the conditioning electronics 150 process an input power signal received from the sensing coil 144 and output, in real time, the measured power values 130a, 130b to the value display 126.

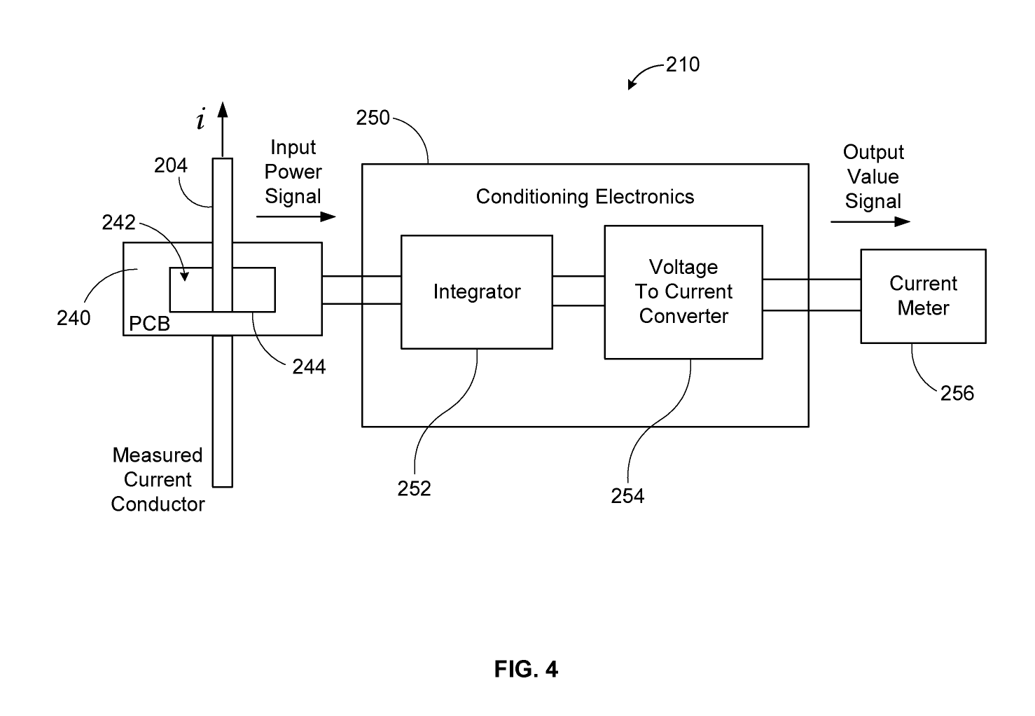

Referring to FIG. 4, a diagrammatic illustrates in more detail the power metering capability of a current sensor 210. The current sensor includes a PCB 204, a sensor 244, and an aperture 242 through which a current-carrying conductor 204 is inserted. An input power signal is provided by the sensor 244 to conditioning electronics 250, which include, for example, an integrator 252 and a voltage-to-current converter 254. The conditioning electronics 250 process the inputted power signal and provide an output value signal indicative of the measured power in the conductor 204. For example, the measure power can be indicated in a current meter 256, which can include a value display such as the value display 126 discussed above.

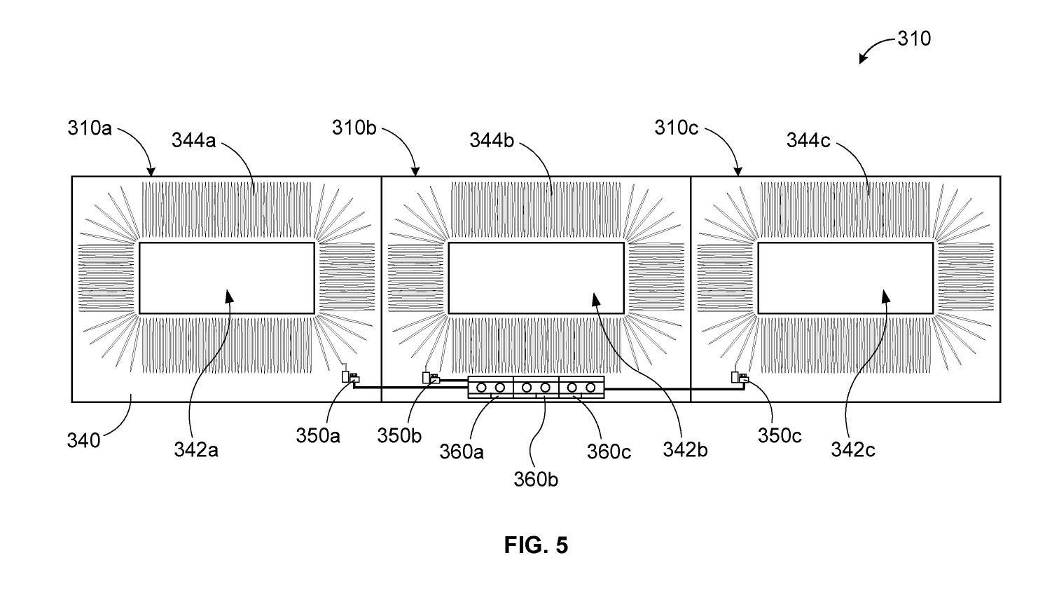

Referring to FIG. 5, a multiple-phase current sensor arrangement 310 includes three current sensors 310a-310c printed on a single PCB 340. The three-phase arrangement 310 works properly in spite of high magnetic fields encountered. Each of the current sensors 310a-310c includes a respective non-ferromagnetic core 342a-342c, sensing coil 344a-344c, conditioning electronics 350a-350c, and connector terminals 360a-360c. The connector terminals 360a-360c are positioned such that a single connection is required to connect the PCB 340 with a power interface. Accordingly, an installer only has to make a single connection in which the interface requires insertion of the connector terminals 360a-360c into a receiving power terminal.

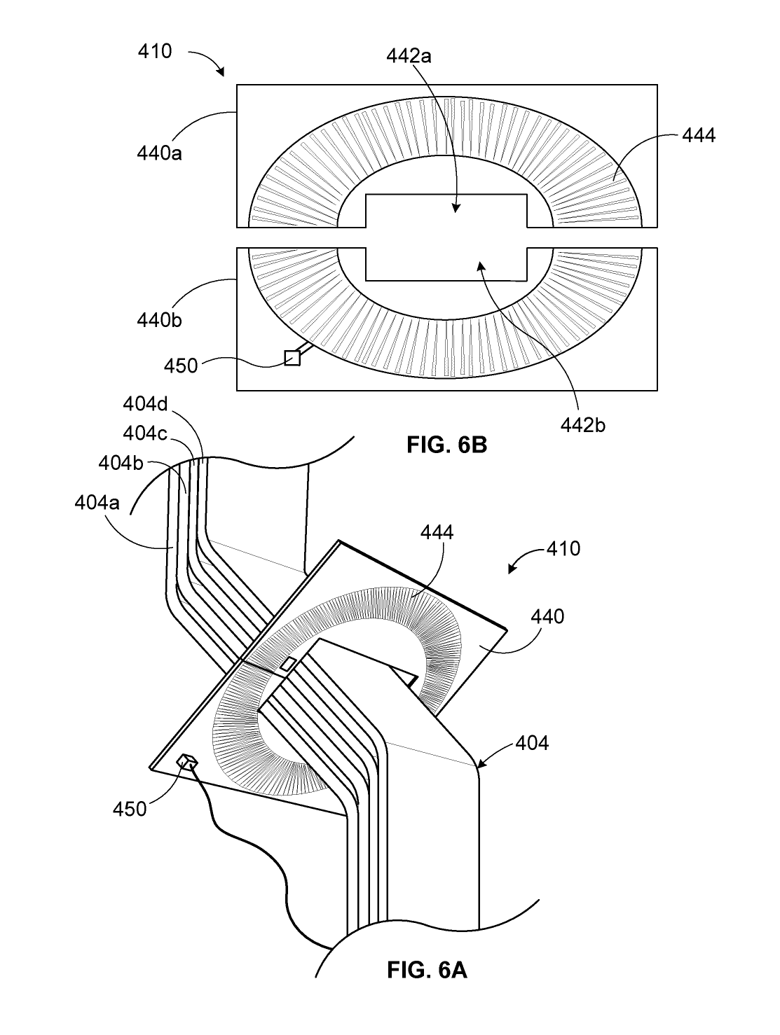

Referring to FIGS. 6A and 6B, another alternative embodiment is directed to a current sensor 410 in which a PCB 440 is split into two sections 440a, 440b to facilitate allocation of a conductor arrangement 404. Each of the two sections 440a, 440b has an associated internal aperture 442a, 442b that, when coupled, form an internal non-ferromagnetic core with a rectangular profile.

The rectangular profile is useful to accommodate the rectangular profile of the conductor arrangement 404, which has a stacked configuration that includes four individual current conductors 404a-404d. The current sensor 440 includes embedded conditioning electronics 450 that are adapted, according to one example, to process high current measurement (e.g., up to about 4,000 Amperes).

The two sections 440a, 440b of the PCB 440 are useful in allocating the conductor arrangement 404 within the non-ferromagnetic core defined by the internal apertures 442a, 442b. To allocate the conductor arrangement 404 such that it passes through the current sensor 410, the two sections 440a, 440b are initially separated. After locating the conductor arrangement 404 within a first aperture 442a, a second section 440b is moved in contact with a first section 440a to make complete the PCB 440. The split board design of the PCB 440 is beneficial for easy installation in new systems or for retrofitting old systems.

While particular embodiments, aspects, and applications of the present invention have been illustrated and described, it is to be understood that the invention is not limited to the precise construction and compositions disclosed herein and that various modifications, changes, and variations may be apparent from the foregoing descriptions without departing from the spirit and scope of the invention as defined in the appended claims. For example, the current sensor can have an elliptical or oval shape that provides increased turn density for the coil and good sensing accuracy.

What is claimed is:

1. An electrical system comprising:
a power distribution system having a current conductor; and
a current sensor for directly monitoring electrical power in the current conductor, the current sensor including
(a) a printed circuit board (PCB) with a non-ferromagnetic core through which the current conductor is inserted,
(b) a current transducer for sensing the electrical power in the current conductor, the current transducer being in the form of a sensing coil printed around the non-ferromagnetic core, and
(c) conditioning electronics embedded into the PCB for processing a data signal based on the monitored electrical power of the current conductor.

2. The electrical system of claim 1, further comprising a distribution enclosure for the power distribution system, the distribution enclosure housing the current conductor and the current sensor.

3. The electrical system of claim 2, wherein the distribution enclosure includes a value display exteriorly mounted to display in real time measured values of the monitored electrical power.

4. The electrical system of claim 3, wherein the measured values include at least one of a current value and a voltage value.

5. The electrical system of claim 1, wherein the current sensor has an electrical output range of about one ampere to about five amperes.

6. The electrical system of claim 1, wherein the conditioning electronics include an integrator and a voltage-to-current converter.

7. The electrical system of claim 1, wherein the sensing coil is a Rogowski coil.

8. The electrical system of claim 1, wherein the current sensor has a multi-phase arrangement in which at least one additional current transducer monitors an additional current conductor, the PCB having at least one additional non-ferromagnetic core around which an additional sensing coil is printed, the current sensor including additional conditioning electronics for the additional current transducer to process a data signal associated with the additional current conductor which is inserted through the additional non-ferromagnetic core.

9. The electrical system of claim 1, wherein the PCB is split into at least two board sections to accommodate insertion of the current conductor within the non-ferromagnetic core.

10. The electrical system of claim 1, wherein the non-ferromagnetic core has a shape selected from a group consisting of a circular shape, an oval shape, and a rectangular shape.

11. An electrical power distribution system comprising:
an enclosure having an exterior value display, the value display displaying measured electrical values;
a current conductor enclosed within the enclosure;
a current sensor for directly monitoring electrical power in the current conductor, the current sensor being enclosed within the enclosure and including
(a) a coreless printed circuit board (PCB) through which the current conductor is inserted,
(b) a current transducer for sensing the electrical power in the current conductor, the current transducer being a sensing coil printed around an internal aperture of the PCB, and
(c) electronics embedded in the PCB for receiving an input power signal from the current transducer and outputting, in real time, the measured electrical values to the value display.

12. The electrical power distribution system of claim 11, wherein the measured electrical values include at least one of a current value and a voltage value.

13. The electrical power distribution system of claim 11, wherein the current sensor has an electrical output range of about one ampere to about five amperes.

14. The electrical power distribution system of claim 11, wherein the conditioning electronics include an integrator and a voltage-to-current converter.

15. The electrical power distribution system of claim 11, wherein the sensing coil is a Rogowski coil.

16. The electrical power distribution system of claim 11, wherein the current sensor has a multi-phase arrangement in which at least one additional current transducer monitors an additional current conductor, the PCB having at least one additional internal aperture around which an additional sensing coil is printed, the current sensor including additional embedded electronics for monitoring electrical power in the additional current conductor.

17. The electrical power distribution system of claim 11, wherein the PCB is split into at least two board sections to accommodate insertion of the current conductor within the internal aperture of the PCB.

18. The electrical power distribution system of claim 11, wherein the internal aperture of the PCB has a shape selected from a group consisting of a circular shape, an oval shape, and a rectangular shape.

19. The electrical power distribution system of claim 11, wherein the current conductor is selected from a group consisting of a cable, a flat lamination, and a flat extrusion.

20. The electrical power distribution system of claim 11, wherein the current sensor has an electrical output range of about one thousand amperes or more.
